(19) United States
(12) Patent Application Publication
(10) Pub. No.: US 2009/0162800 A1
(43) Pub. Date: Jun. 25, 2009

(54) Process for Imaging a Photoresist Coated over an Antireflective Coating

(76) Inventors: David Abdallah, Bernardsville, NJ (US); Alberto Dioses, Doylestown, PA (US); Allen Timko, Flemington, NJ (US); Ruzhi Zhang, Pennington, NJ (US)

Correspondence Address: SANGYA JAIN;AZ ELECTRONIC MATERIALS USA CORP., 70 MEISTER AVENUE, SOMERVILLE, NJ, 08876, US

(21) Appl. No.: 11/961,581

(22) Filed: Dec. 20, 2007

(51) Int. Cl. G03F 7/30

(52) U.S. Cl. 430/326

(57) ABSTRACT

The process of the present invention relates to imaging a photoresist film coated over an antireflective coating film comprising a) forming an antireflective coating film from an antireflective coating composition, where the composition comprises a siloxane polymer, b) treating the antireflective film with an aqueous alkaline treating solution, c) rinsing the antireflective film treated with an aqueous rinsing solution, d) forming a coating of a photoresist over the film of the antireflective coating composition, e) imagewise exposing the photoresist film, and, f) developing the photoresist with an aqueous alkaline developing solution.

### FIELD OF INVENTION

The present invention relates to a process for imaging a photoresist film coated over a film of an absorbing antireflective coating composition, where the process comprises a step of treating the antireflective film with an aqueous alkaline treating solution. The process is especially useful for imaging photoresists using radiation in the deep and extreme ultraviolet (uv) region.

### BACKGROUND OF THE INVENTION

Photoresist compositions are used in microlithography processes for making miniaturized electronic components such as in the fabrication of computer chips and integrated circuits. Generally, in these processes, a thin coating of film of a photoresist composition is first applied to a substrate material, such as silicon based wafers used for making integrated circuits. The coated substrate is then baked to evaporate any solvent in the photoresist composition and to fix the coating onto the substrate. The baked coated surface of the substrate is next subjected to an image-wise exposure to radiation.

This radiation exposure causes a chemical transformation in the exposed areas of the coated surface. Visible light, ultraviolet (UV) light, electron beam and X-ray radiant energy are radiation types commonly used today in microlithographic processes. After this image-wise exposure, the coated substrate is treated with a developer solution to dissolve and remove either the radiation-exposed or the unexposed areas of the photoresist.

The trend towards the miniaturization of semiconductor devices has led to the use of new photoresists that are sensitive to lower and lower wavelengths of radiation and has also led to the use of sophisticated multilevel systems to overcome difficulties associated with such miniaturization.

Absorbing antireflective coatings and underlayers in photolithography are used to diminish problems that result from back reflection of light from highly reflective substrates. A film of an antireflective coating composition coated beneath a photoresist and above a reflective substrate provides significant improvement in lithographic performance of the photoresist. Typically, the bottom antireflective coating is applied on the substrate and then a layer of photoresist is applied on top of the antireflective coating. The antireflective coating is cured to prevent intermixing between the antireflective coating and the photoresist. The photoresist is exposed imagewise and developed. The antireflective coating in the exposed area is then typically dry etched using various etching gases, and the photoresist pattern is thus transferred to the substrate.

The antireflective coating film, especially one comprising silicon, may have a hydrophobic surface which can form footing and scum at the photoresist and antireflective coating film interface during development or inhibit proper coating of the photoresist on top of the silicon containing antireflective coating film through de-wetting which can lead to voids and non-uniform photoresist film coatings. Silane priming agents are used to make surfaces hydrophobic, but none are capable of making a surface more hydrophilic. The use of priming agents to make a surface more hydrophobic are needed for forming coating on substrates like SiO₂. However, siloxane films introduce a different problem, unlike SiO₂, they can have many hydrophobic functionalities expressed at the film surface and thus make the films surface highly hydrophobic. It is believed that in siloxane antireflective films the hydrophobic moieties are driven to be organized at the film surface to minimize surface energies.

The present invention relates to a novel process which comprises treating the surface of the siloxane antireflective coating film with an aqueous alkaline (also known as base) solution, thereby increasing the hydrophilicity of the film. The novel process results in the defect free uniformly coated photoresist film which after development exhibits good lithographic performance, especially being free of scum and defects at the photoresist and antireflective coating film interface.

### SUMMARY OF THE INVENTION

The present invention relates to a process for imaging a photoresist film coated over an antireflective coating film comprising a) forming an antireflective coating film from an antireflective coating composition, where the composition comprises a siloxane polymer, b) treating the antireflective film with an aqueous alkaline treating solution, c) rinsing the antireflective film treated with an aqueous rinsing solution, d) forming a coating of a photoresist over the film of the antireflective coating composition, e) imagewise exposing the photoresist film, and, f) developing the photoresist with an aqueous alkaline developing solution.

### DESCRIPTION OF THE INVENTION

The invention relates to a process for imaging a photoresist film, where the photoresist film is coated over a film of an antireflective coating which has been treated with an aqueous alkaline treating solution. The present invention relates to a process for changing the surface hydrophobicity of a siloxane polymer film to one that is more hydrophilic by the treatment of the film surface with an aqueous alkaline solution. The photoresist is capable of being imaged with an exposure radiation in the range of about 250 nm to about 10 nm.

The process of the present invention relates to imaging a photoresist film coated over an antireflective coating film comprising a) forming an antireflective coating film from an antireflective coating composition, where the composition comprises a siloxane polymer, b) treating the antireflective film with an aqueous alkaline treating solution, c) rinsing the antireflective film treated with an aqueous rinsing solution, d) forming a coating of a photoresist over the film of the antireflective coating composition, e) imagewise exposing the photoresist film, and, f) developing the photoresist with an aqueous alkaline developing solution. The films are baked to remove the coating solvent. After imagewise exposure the photoresist may be given a postexposure bake.

The antireflective coating film, especially one comprising silicon and oxygen, may have a hydrophobic surface which can form footing and scum at the photoresist and antireflective coating film interface during development or inhibit proper coating of the photoresist on top of the silicon containing antireflective coating film through de-wetting which can lead to voids and non-uniform photoresist film coatings. Hydrophobic surfaces are associated with having a high water contact angle. Thus, water contact angles are a good indicator of surface hydrophobicity or hydrophilicity. Photoresists, typically, have surfaces with lower hydrophobicity as compared to silicon containing antireflective coatings. It is preferred that the water contact angle or hydrophobicity of the exposed photoresist and the antireflective coating be similar in order to minimize footing and scumming at the interface during development and also to avoid dewetting of photoresist films coated above the silicone films.

The siloxane (silicone) polymer of the antireflective coating comprises a chromophore group and a group capable of being hydrolysed in the presence of a base (alkali), where the chromophore group is one which is capable of absorbing the radiation used to expose the photoresist film coated over the antireflective coating film. The chromophore group is capable of absorbing the radiation used to expose the photoresist coated over the film of the present antireflective coating composition and the chromophore group can be groups such as disilane groups or aromatic groups; examples of chromophore groups are pentamethylsilane, unsubstituted phenyl and substituted phenyl, particularly for 193 nm radiation. Other chromophores may also be used, such as unsubstituted naphthyl, substituted naphthyl, unsubstituted anthracyl, and substituted anthracyl for 248 nm radiation. The chromophore group may be substituted with moieties such as hydroxy, esters, ethers, alkyl carboxyl, etc. The chromophore group may be directly linked to the backbone structure of the polymer or be part of an organic moiety attached to the backbone of the polymer.

The polymer of the antireflective coating composition is a siloxane polymer, where the polymer comprises an absorbing chromophore and a group capable of being hydrolysed in the presence of a base or alkali. The group capable of being hydrolysed in the presence of a base can be a —Si—X moiety attached to the siloxane polymer, where the —Si—X moiety is hydrolysed by the base or alkali to give a —Si—OH moiety, and where X is a base hydrolysable group. Examples of base hydrolysable group, X, are alkoxy (OR), chloride (CI), acyloxy (OC(O)R), ketoxime (ON—C), etc., and where R is an alkyl group. In one embodiment X is alkoxy. In the antireflective coating composition solution, the —Si—X moiety may be introduced in the polymer to stabilize the silanol (—Si—OH) moiety or be a residual moiety from the process from which the resin is made, but the —Si—X group can lead to a hydrophobic film surface, Hydrophobic film surfaces can cause the formation of scum and footing at the photoresist/antireflective film interface. It is desirable to reduce the hydrophobicity of the antireflective film interface to be similar to that of the photoresist film. The present invention discloses a novel process for reducing the hydrophobicity, or increasing the hydrophilicity, of the antireflective coating film. Once the antireflective coating film has been formed, some of the —Si—X moieties on the surface of the film can be hydrolysed by a base to form hydrophilic —Si—OH moieties on the surface of the film, by treating the surface of the film with an aqueous alkaline solution, and hence making the film surface more hydrophilic. Usually the silicone films are completely crosslinked so that the action of the aqueous base solution only hydrolyses the surface of the film. The degree of hydrophilicity, which can be measured by the reduction in water contact angle, can be controlled by optimizing factors such as the time the surface is exposed to the base, the temperature of the base, the temperature of the substrate with the siloxane film, the type of base, the concentration of the aqueous base solution, etc.

The siloxane polymer in the antireflective coating composition is a siloxane polymer comprising a silicon and oxygen (—Si—O—) structure and also comprising an absorbing chromophore and a group capable of being hydrolysed in the presence of a base, as described herein. Siloxane polymers are also those that reduce the dry etch rate of the film under gaseous dry etching conditions. During dry etching, siloxane polymers can form hard masks. When sandwiched between organic films such as a photoresist and an organic underlayer. Siloxane polymers of the present composition are crosslinkable either through a crosslinking group present in the polymer or have or can form a functionality which can crosslink with a crosslinking compound. The crosslinked polymer prevents intermixing with the photoresist film coated over the film comprising the siloxane composition. The crosslinking group is a group such as acetoxy alkyl (such as acetoxyethyl), epoxy, Si—OH and a group that can form a Si—OH. A crosslinking group can also be a labile base hydrolysable group which hydrolyses to form a crosslinkable Si—OH group, and the labile base hydrolysable group can be selected from alkoxy (OR), chloride (CI), acyloxy (OC(O)R) or ketoxime (ON═C), where these groups provide a crosslinking site in the bulk of the film, but can be hydrolysed on the surface by a base. The siloxane polymers are such as those disclosed in U.S. patent applications with Ser. Nos. 11/425,813, 11/425,817 and 11/676,671, and incorporated herein by reference, providing they comprise an absorbing chromophore and a group capable of being hydrolysed in the presence of a base to give a hydrophilic group. An example of a siloxane polymer is a polymer comprising at least one repeating unit of formula ((A)ⱼR₁SiO_{(3-j)/2}) and at least one repeating unit of formula ((A)ₖR₂SiO_{(3-k)/2}), where each R₁ individually is the same or different chromophore which absorbs at any actinic wavelength; each R₂ is a base hydrolysable as described previously; each A is an unreacted functional group of a monomer which forms either of the above repeating units; j and k are each integers that fall within the range 0≦j≦1 and 0≦k≦1, the ratio of R₁ to R₂ being from about 1:99 to about 60:40. The polymer can also comprise an additional unit of formula (R_{f})_{w}(R₉)_{z}SiO_{4-w-z)/2}, Where R_{f} and R_{g} are each individually selected from R₁, R₂ alkyl, alkenyl, cycloalkyl, and aralkyl groups which can be unsubstituted or substituted; and w and z are each integers within the limits 0≦(w or z)≦2 with the proviso that (4-w-z) does not equal O, Suitable substituents include those which, in the context of this invention, do not alter the properties of the groups, such as e.g., a halogen atom (e.g., fluorine, chlorine, bromine, iodine), hydroxy, alkoxy, mercapto, alkylmercapto, nitro, nitroso, cyano, sulfoxy, and the like. Examples of alkyl include methyl, butyl, isoamyl, and the like, alkenyl such as vinyl, allyl, and the like, cycloalkyl such as cyclohexyl, cyclopentyl, adamantyl, and the like, alkoxy such as, for example, methoxy group, ethoxy group, hydroxyethoxy group, propoxy group, hydroxypropoxy group, n-butoxy group, isobutoxy group, sec-butoxy group and t-butoxy group, aralkyl such as benzyl group, phenethyl group and cumyl group, aryloxy such as phenoxy group, and aryloxycarbonyl group such as benzoyloxy group. The polymer contains repeating units ((A)ⱼR₁SiO_{(3-j)/2}) and ((A)ₖR₂SiO_{(3-k)/2}), which may be prepared by methods known to those skilled in the art, for example, by hydrolytic condensation reactions of trifunctional organosilicon monomers such as RSiA₃, RSiCl₃, a silane ester (RSi(ORₓ)₃ where Rₓ can be an alkyl group, RSi(acyloxy)₃, or RSi(alkylketoxime)₃, or a hydrolyzed form of the above, where R can be R₁, R₂, alkyl, alkenyl, cycloalkyl, and aralkyl groups which can be unsubstituted or substituted. Further information on preparing polymers of the present invention can be found in U.S. Pat. No. 5,290,354; U.S. Pat. No. 5,320,868, and U.S. Pat. No. 6,770,726. These reactions can form small oligomers, complex resins and networks.

Another example of a siloxane or organosiloxane polymer is one which contains SiO units within the polymer structure, where the SiO units may be within the polymer backbone and/or pendant from the polymer backbone. Siloxane polymers known in the art may be used. Various types of siloxane polymers are known in the art and are exemplified in the following references which are incorporated herein by reference, US 2006/0194916, U.S. Pat. No. 6,069,259, U.S. Pat. No. 6,420,088, U.S. Pat. No. 6,515,073, and US 2005/0277058. Examples of siloxane polymers, without limitation, are linear polymers and ladder or network (silsesquioxane) types of polymers or polymers comprising mixtures of linear and network blocks. Polyhedral structures of siloxanes are also known and are part of the invention. In one embodiment the present siloxane polymer comprises units described by (i) and (ii),

(R¹SiO_{3/2}) and (R²SiO_{3/2}) (i),

(R′(R″)SiOx) (ii),

where R¹ is independently a moiety selected from a crosslinking group, base hydrolysable group, and a crosslinking group which is also a base hydrolysable group, and mixture of theses R² is independently a moiety comprising a chromophore group, R′ and R″ are independently selected from R¹ and R², and x=½ or 1, providing at least one of R¹, R², R′ and R″ in the polymer is a base hydrolysable group described previously. Typically R² is a chromophore group such as an aromatic or aryl moiety, as described herein. The crosslinking group is a group such as epoxy. A crosslinking group which is also a base hydrolysable group can be alkoxy (OR), chloride (CI), acyloxy (OC(O)R) or ketoxime (ON═C), and where R is an alkyl group, and where these groups provide a crosslinking site in the bulk of the film, but at the surface some of these groups are not involved in crosslinking and are available for base hydrolysisis. In another embodiment the siloxane polymer comprises linear polymeric units described by (iii) and (iv),

-(A¹(R¹)SiO)— (iii), and

-((A²)R²SiO)— (iv),

where, R¹ and R² are as above, A¹ and A² are independently hydroxyl, R¹, R², halide (such as fluoride and chloride), alkyl, OR, OC(O)R, alkylketoxime, unsubstituted aryl and substituted aryl, alkylaryl, alkoxy, acyl and acyloxy, R is selected from alkyl, unsubstituted aryl and substituted aryl, and providing one of groups in the polymer is a base hydrolysable group. In yet another embodiment the siloxane polymer contains mixtures of network and linear units, that is, network units comprising (i) and/or (ii) and linear units comprising (iii) and/or (iv). Generally, a polymer comprising predominantly the silsesquioxane or network type of units are preferred, since they provide superior dry etch resistance, but mixtures can also be useful. The polymer of the antireflective coating composition may further comprise one or more other silicon containing units, such as

—(R³SiO_{3/2})— (v),

where R³ is independently, hydroxyl, hydrogen, halide

(such as fluoride and chloride), alkyl, OC(O)R, alkylketoxime, aryl, alkylaryl, alkoxy, acyl and acyloxy, and R is selected from alkyl, unsubstituted aryl and substituted aryl,

—(SiO_{4/2})— (vi),

-((A¹)A²SiOx) (vii),

where x=½ or 1, A¹ and A² are independently hydroxyl, hydrogen, halide (such as fluoride and chloride), alkyl, OR, OC(O)R, alkylketoxime, aryl, alkoxy, alkylaryl, acyl and acyloxy; and mixtures of these units. In one embodiment the polymer comprises any number of units (i) to (vii), providing there is an absorbing group and a crosslinking group of structure (1) attached to a siloxane polymer. In another embodiment the polymer comprises units (i) and (v). One example of the polymer may comprise the structure,

(R¹SiO_{3/2})ₐ(R²SiO_{3/2})_{b}(R³SiO_{3/2})_{c}(SiO_{4/2})_{d}

where, R¹ is independently a moiety comprising a crosslinking group of structure 1, R² is independently a moiety comprising a chromophore group, R³ is independently selected from hydroxyl, hydrogen, halide (such as fluoride and chloride), alkyl, OR, OC(O)R, alkylketoxime, aryl, alkylaryl, alkoxy, acyl and acyloxy; providing one of R¹ or R³ is a base hydrolysable group, where R is selected from alkyl, unsubstituted aryl and substituted aryl; 0≦a≦1; 0≦b≦1; 0≦c≦1; 0≦d<1. In one embodiment of the polymer the concentration of the monomeric units are defined by 0.1≦a≦0.9, 0.05≦b≦0.75, 0.1<c and/or d<0.8.

Examples of the polymers include poly(phenyl siloxane-co-acetoxy siloxane).

In the above definitions and throughout the present specification, unless otherwise stated the terms used are described below.

Alkyl means linear or branched alkyl having the desirable number of carbon atoms and valence. The alkyl group is generally aliphatic and may be cyclic or acyclic (i.e. noncyclic). Suitable acyclic groups can be methyl, ethyl, n- or iso-propyl, n-iso, or tert-butyl, linear or branched pentyl, hexyl, heptyl, octyl, decyl, dodecyl, tetradecyl and hexadecyl. Unless otherwise stated, alkyl refers to 1-10 carbon atom moeity. The cyclic alkyl groups may be mono cyclic or polycyclic. Suitable example of mono-cyclic alkyl groups include substituted cyclopentyl, cyclohexyl, and cycloheptyl groups. The substituents may be any of the acyclic alkyl groups described herein. Suitable bicyclic alkyl groups include substituted bicyclo[2.2.1]heptane, bicyclo[2.2.2]octane, bicyclo[3.2.1.]octane, bicyclo[3.2.2]nonane, and bicyclo[3.3.2]decane, and the like. Examples of tricyclic alkyl groups include tricyclo[5.4.0.0.^{2.9}]undecane, tricyclo[4.2.1.2.^{7,9}]undecane, tricyclo[5.3.2.0.⁴.9]dodecane, and tricyclo[5.2.1.0.^{2,6}]decane. As mentioned herein the cyclic alkyl groups may have any of the acyclic alkyl groups as substituents.

Aryl groups contain 6 to 24 carbon atoms including phenyl, tolyl, xylyl, naphthyl, anthracyl, biphenyls, bis-phenyls, tris-phenyls and the like. These aryl groups may further be substituted with any of the appropriate substituents e.g. alkyl, alkoxy, acyl or aryl groups mentioned hereinabove. Similarly, appropriate polyvalent aryl groups as desired may be used in this invention. Representative examples of divalent aryl groups include phenylenes, xylylenes, naphthylenes, biphenylenes, and the like.

Alkoxy means straight or branched chain alkoxy having 1 to 10 carbon atoms, and includes, for example, methoxy, ethoxy, n-propoxy, isopropoxy, n-butoxy, isobutoxy, tert-butoxy, pentyloxy, hexyloxy, heptyloxy, octyloxy, nonanyloxy, decanytoxy, 4-methylhexyl oxy, 2-propylheptyloxy, and 2-ethyloctyloxy.

Aralkyl means aryl groups with attached substituents. The substituents may be any such as alkyl, alkoxy, acyl, etc. Examples of monovalent aralkyl having 7 to 24 carbon atoms include phenylmethyl, phenylethyl, diphenylmethyl, 1,1- or 1,2-diphenylethyl, 1,1-, 1,2-, 2,2-, or 1,3-diphenylpropyl, and the like. Appropriate combinations of substituted aralkyl groups as described herein having desirable valence may be used as a polyvalent aralkyl group.

Furthermore, and as used herein, the term “substituted” is contemplated to include all permissible substituents of organic compounds. In a broad aspect, the permissible substituents include acyclic and cyclic, branched and unbranched, carbocyclic and heterocyclic, aromatic and non-aromatic substituents of organic compounds. Illustrative substituents include, for example, those described hereinabove. The permissible substituents can be one or more and the same or different for appropriate organic compounds. For purposes of this invention, the heteroatoms such as nitrogen may have hydrogen substituents and/or any permissible substituents of organic compounds described herein which satisfy the valencies of the heteroatoms. This invention is not intended to be limited in any manner by the permissible substituents of organic compounds.

In one embodiment the antireflective coating composition comprises a siloxane polymer which is self curing, that is a crosslinking agent, curing catalyst or thermal acid generator is not required.

Various types of crosslinking agents and curing agents may be added to the composition to crosslink the soloxane polymer. The anitireflective composition used in the inventive process comprises a siloxane polymer and a curing catalyst or a crosslinking agent. The curing catalyst may be selected from any that can cure the silicon polymer. Examples of curing catalysts are salts, which may also be photoacid generators and thermal acid generators. Examples of curing salts are disclosed in U.S. applications U.S. Ser. No. 11/550,459, U.S. Ser. No. 11/676,673 and U.S. Ser. No. 11/425,817, incorporated herein by reference, but other curing salts may also be used. More than one catalyst may be used. The (i) a strong base catalyst and/or strong base generator source; or (ii) a sulfuric acid generator which decomposes at a temperature less than or equal to about 500° C. are well known to those of ordinary skill in the art as is their method of making, which can be based on neutralizing acids with the base of interest.

One example of a salt is a strong base catalyst and/or strong base generator source which can be represented by the formula Z⁺A⁻, where Z⁺ is a cation such as tetraalkylammonium, tetraallkylphosphonium, trialkylmonoarylammonium, trialkylmonoarylphosphonium, dialkyldiarylammonium, dialkyldiarylphosphonium, monoalkyltriarylammonium, monoalkyltriarylphosphonium, tetraarylammonium, tetraarylphosphonium, unsubstituted or substituted iodonium, and unsubstituted or substituted sulfonium. Examples of the mentioned cations include tetramethylammonium, tetrabutylammonium, tetraphenylammonium, tetramethylphosphonium, tetraphenylphosphonium, trimethylphenylammonium, trimethylphenylphosphonium, dimethyldiphenylammonium, dimethyldiphenylphosphonium, triphenylsulfonium, (4-t-butylphenyl)diphenylsulfonium, diphenylodonium, and bis(4-t-butylphenyl)iodonium) and the like, etc. A is an anion containing a group such as halide, hypohalite, halite, halate, perhalate, hydroxide, monocarboxylate, dicarboxylate, carbonate, bicarbonate, silanolate, alkoxide, aryloxide, nitrate, azide, peroxymonosulfate, peroxydisulfate, dihydrogen phosphate, phosphate, sulfate, bisulfate, sulfonate, and guanidine, as well as the hydrates thereof, and mixtures thereof. For the anion, the anion will contain one of the aforementioned groups or the group itself will be the anion. Monocarboxylate refers to anions of organic acids containing one carboxy group with the hydrogen removed and include, for example, acetate, formate, proprionate, and the like. Dicarboxylate refers to anions of organic acids containing two carboxy groups where one or both of the hydrogens are removed and include succinate, malonate, monomalonate (where only one hydrogen is removed), adipate, and the like.

For (ii) a sulfuric acid generator which decomposes at a temperature less than or equal to about 500° C., a sulfuric acid generator is a compound that will generate sulfuric acid when heated. Examples of the sulfuric acid generator which decomposes at a temperature less than or equal to about 500° C. can include sulfuric acid, hydrogen sulfate or sulfate salts of trialkylamine, unsubstituted or substituted dialkylmonocyloalkylamine, unsubstituted or substituted monoalkyldicycloalkylamine, unsubstituted or substituted tricycloalkylamine, triarylamine, unsubstituted or substituted diarylmonoalkylamine, unsubstituted or substituted monoaryldialkylamine, unsubstituted or substituted triarylamine, unsubstituted or substituted aziridine, unsubstituted or substituted azetidine, unsubstituted or substituted pyrrol, unsubstituted or substituted pyridine, unsubstituted or substituted piperidine, or unsubstituted or substituted piperazine, such as triethylamine hydrogen sulfate, tributylamine hydrogen sulfate, piperazine sulfate, and the like.

A variety of crosslinking agents can be used in the composition of the present invention. Any suitable crosslinking agents that can crosslink the polymer in the presence of an acid may be used. Examples, without limitation, of such crosslinking agents are resins containing melamines, methylols, glycoluril, polymeric glycolurils, benzoguanamine, urea, hydroxy alkyl amides, epoxy and epoxy amine resins, blocked isocyanates, and divinyl monomers. Monomeric melamines like hexamethoxymethyl melamine; glycolurils like tetrakis(methoxymethyl)glycoluril; and aromatic methylols, like 2,6 bishydroxymethyl p-cresol may be used. Crosslinking agents disclosed in US 2006/0058468 and incorporated herein by reference, where the crosslinking agent is a polymer obtained by reacting at least one glycoluril compound with at least one reactive compound containing at least one hydroxy group and/or at least one acid group may be used.

The antireflective composition may further comprise a thermal acid generator. The acid generator of the composition is a thermal acid generator capable of generating a strong acid upon heating. The thermal acid generator (TAG) used in the present invention may be any one or more that upon heating generates an acid which can react with the cyclic ether and propagate crosslinking of the polymer present in the invention, particularly preferred is a strong acid such as a sulfonic acid. Preferably, the thermal acid generator is activated at above 90° C. and more preferably at above 120°, and even more preferably at above 150° C. The photoresist film is heated for a sufficient length of time to react with the coating. Examples of TAGs are nitrobenzyl tosylates, such as 2-nitrobenzyl tosylate, 2,4-dinitrobenzyl tosylate, 2,6-dinitrobenzyl tosylate, 4-nitrobenzyl tosylate; benzenesulfonates such as 2-trifluoromethyl-6-nitrobenzyl 4-chlorobenzenesulfonate, 2-trifluoromethyl-6-nitrobenzyl 4-nitro benzenesulfonate; phenolic sulfonate esters such as phenyl, 4-methoxybenzenesulfonate; alkyl ammonium salts of organic acids, such as triethylammonium salt of 10-camphorsulfonic acid. Iodonium salts are preferred and can be exemplified by iodonium fluorosulfonates, iodonium tris(fluorosulfonyl)methide, iodonium bis(fluorosulfonyl)methide, iodonium bis(fluorosulfonyl)imide, iodonium quaternary ammonium fluorosulfonate, iodonium quaternary ammonium tris(fluorosulfonyl)methide, and iodonium quaternary ammonium bis(fluorosulfonyl)imide. A variety of aromatic (anthracene, naphthalene or benzene derivatives) sulfonic acid amine salts can be employed as the TAG, including those disclosed in U.S. Pat. No. 3,474,054, U.S. Pat. No. 4,200,729, U.S. Pat. No. 4,251,665 and U.S. Pat. No. 5,187,019. Preferably the TAG will have a very low volatility at temperatures between 170-220° C. Examples of TAGs are those sold by King Industries under Nacure and CDX names. Such TAG's are Nacure 5225, and CDX-2168E, which is a dodecylbenzene sulfonic acid amine salt supplied at 25-30% activity in propylene glycol methyl ether from King Industries, Norwalk, Conn. 06852, USA. Strong acids with pKa in the range of about −1 to about −16 are preferred, and strong acids with pKa in the range of about −10 to about −16 are more preferred.

Examples of photoacid generators are without limitation, onium salts, sulfonate compounds, nitrobenzyl esters, triazines, etc, which may further added to the antireflective composition. The preferred photoacid generators are onium salts and sulfonate esters of hydroxyimides, specifically diphenyl iodonium salts, triphenyl sulfonium salts, dialkyl iodonium salts, triakylsulfonium salts, and mixtures thereof.

The antireflection coating composition of the present invention contains 1 weight % to about 11 weight % of the siloxane polymer, and preferably 4 weight % to about 10 weight % of total solids. The thermal acid generator, curing agent or crosslinking agent may be incorporated in a range from about 0.1 to about 10 weight % by total solids of the antireflective coating composition, preferably from 0.3 to 5 weight % by solids, and more preferably 0.5 to 2.5 weight % by solids.

The solid components of the antireflection coating composition are mixed with a solvent or mixtures of solvents that dissolve the solid components of the antireflective coating. Suitable solvents for the antireflective coating composition may include, for example, a glycol ether derivative such as ethyl cellosolve, methyl cellosolve, propylene glycol monomethyl ether, diethylene glycol monomethyl ether, diethylene glycol monoethyl ether, dipropylene glycol dimethyl ether, propylene glycol n-propyl ether, or diethylene glycol dimethyl ether; a glycol ether ester derivative such as ethyl cellosolve acetate, methyl cellosolve acetate, or propylene glycol monomethyl ether acetate (PGMEA); carboxylates such as ethyl acetate, n-butyl acetate and amyl acetate; carboxylates of di-basic acids such as diethyloxylate and diethylmalonate; dicarboxylates of glycols such as ethylene glycol diacetate and propylene glycol diacetate; and hydroxy carboxylates such as methyl lactate, ethyl lactate, ethyl glycolate, and ethyl-3-hydroxy propionate; a ketone ester such as methyl pyruvate or ethyl pyruvate; an alkoxycarboxylic acid ester such as methyl 3-methoxypropionate, ethyl 3-ethoxypropionate, ethyl 2-hydroxy-2-methylpropionate, or methylethoxypropionate; a ketone derivative such as methyl ethyl ketone, acetyl acetone, cyclopentanone, cyclohexanone or 2-heptanone; a ketone ether derivative such as diacetone alcohol methyl ether; a ketone alcohol derivative such as acetol or diacetone alcohol; lactones such as butyrolactone; an amide derivative such as dimethylacetamide or dimethylformamide, anisole, and mixtures thereof.

The novel composition may further contain a photoacid generator, examples of which without limitation, are onium salts, sulfonate compounds, nitrobenzyl esters, triazines, etc. The preferred photoacid generators are onium salts and sulfonate esters of hydroxyimides, specifically diphenyl iodnium salts, triphenyl sulfonium salts, dialkyl iodonium salts, triakylsulfonium salts, and mixtures thereof.

The antireflective coating composition comprises the polymer, and the thermal acid generator of the instant invention and a suitable solvent or mixtures of solvents. Other components may be added to enhance the performance of the coating, e.g. monomeric dyes, lower alcohols, surface leveling agents, adhesion promoters, antifoaming agents, etc. These may be present at about 0.1 to about 10 weight % by total solids of the antireflective coating composition, preferably from 0.3 to 5 weight % by solids, and more preferably 0.5 to 2.5 weight % by solids.

The absorption parameter (k) of the antireflective composition ranges from about 0.05 to about 1.0, preferably from about 0.1 to about 0.8 as measured using ellipsometry. The refractive index (n) of the antireflective coating is also optimized and can range from 1.3 to about 2.0, preferably 1.5 to about 1.8. The n and k values can be calculated using an ellipsometer, such as the J. A, Woollam WVASE VU-32 ™ Ellipsometer. The exact values of the optimum ranges for k and n are dependent on the exposure wavelength used and the type of application. Typically for 193 nm the preferred range for k is 0.05 to 0.75, and for 248 nm the preferred range for k is 0.15 to 0.8. The film thickness ranges from 15 nm to about 200 nm, depending on the exposure wavelength. For a particular exposure wavelength there are two optimum film thickness ranges that provide minimum reflectivity. For 193 nm, the film thickness is in the range of about 20 nm to about 50 nm, or about 80 nm to about 120 nm; for 248 nm, the film thickness is in the range of about 25 nm to about 60 nm or about 85 nm to about 140 nm.

The antireflective coating composition is coated on the substrate using techniques well known to those skilled in the art, such as dipping, spin coating or spraying. The film thickness of the antireflective coating ranges from about 15 nm to about 200 nm. The coating is further heated on a hot plate or convection oven for a sufficient length of time to remove any residual solvent and induce crosslinking, and thus insolubilize the antireflective coating to prevent intermixing between the antireflective coatings. The preferred range of temperature is from about 90° to about 250° C. If the temperature is below 90° C. then insufficient loss of solvent or insufficient amount of crosslinking or curing takes place, and at temperatures above 300° C. the composition may become chemically unstable.

The presently described siloxane antireflective coating may be coated over other layers of antireflective coating compositions, with the siloxane antireflective coating composition being the topmost layer of the antireflective coating layers. The layers beneath the siloxane film may be spin coated organic films or chemical vapor deposited inorganic film, where examples of films are high carbon layers which are novolaks or chemical vapor deposited carbon films, porous polymeric resins with low dielectric constant, etc.

The substrates over which the antireflective coatings are formed can be any of those typically used in the semiconductor industry. Suitable substrates include, without limitation, silicon, silicon substrate coated. With a metal surface, copper coated silicon wafer, copper, aluminum, polymeric resins, porous polymeric resins, silicon dioxide, metals, doped silicon dioxide, silicon nitride, tantalum, polysilicon, ceramics, aluminum/copper mixtures; gallium arsenide and other such Group III/V compounds. The substrate may comprise any number of layers made from the materials described above.

The siloxane antireflective coating film is then treated with an aqueous alkaline solution. The aqueous base solution comprises a base and water, and optionally a surfactant may be added to the solution. The base may be any water soluble base such as tetraalkylammonium hydroxide (TMAH) or choline. Tetramethylammonium hydroxide is preferred. The base can range from about 0.01 to about 10 weight % of the total weight. In one embodiment the base can range from about 2.0 to 2.5 weight % of the total weight. In another embodiment a 2.3 weight % of the total weight of the solution may be used. The treating solution may be applied to the coating by any method which brings the substrate in contact with the solution, such as for example, forming a puddle of the solution on the substrate and then spinning the substrate to remove the solution, or spraying the substrate with the solution, or immersing the substrate in the solution, etc. The length of time that the film is exposed to the solution, the temperature of the solution, normality or concentration of the base, and other parameters may be optimized to obtain an antireflective film with the desired hydrophilicity and lithographic properties. It is desirable to match as closely as possible the hydrophilicity or hydrophobicity of the treated film with that of the photoresist. Typically the photoresist has a water contact angle of about 50° to about 75°. The untreated antireflective coating film of the present invention comprising a siloxane polymer has a water contact angle in the range of about 90° to about 80°. Therefore the treated antireflective coating film can have a water contact angle from about 50° to about 75°, preferably from about 55° to about 70°, or from about 60° to about 70°. It has been unexpectedly been found that the contact angle of the treated film changes very rapidly initially and then stabilizes, depending on the polymer in the antireflective film. The time of exposure to the aqueous base solution for a siloxane film can range from about 20 seconds to about 60 seconds for a 2.3 weight % of TMAH at room temperature, or 20 seconds to about 40 seconds. In a bath treatment the temperature can range from about 0° C. to about 50° C.

After the antireflective film has been treated, the treating solution is removed and the film can be rinsed to clean the surface. A water rinse, especially with deionized water, can be sufficient remove the residual base. The rinse may be done in the same equipment as the treatment with the base solution. The film is then dried. Bath treatment processes would require separate drying equipment.

A film of photoresist is then coated on top of the uppermost siloxane antireflective coating and baked to substantially remove the photoresist solvent. An edge bead remover may be applied after the coating steps to clean the edges of the substrate using processes well known in the art. Photoresists can be any of the types used in the semiconductor industry, provided the photoactive compound in the photoresist and the antireflective coating absorb at the exposure wavelength used for the imaging process.

To date, there are several major deep ultraviolet (uv) exposure technologies that have provided significant advancement in miniaturization, and these use radiation of 248 nm, 193 nm, 157 and 13.5 nm. Photoresists for 248 nm have typically been based on substituted polyhydroxystyrene and its copolymers/onium salts, such as those described in U.S. Pat. No. 4,491,628 and U.S. Pat. No. 5,350,660. On the other hand, photoresists for exposure below 200 nm require non-aromatic polymers since aromatics are opaque at this wavelength. U.S. Pat. No. 5,843.624 and U.S. Pat. No. 6,866,984 disclose photoresists useful for 193 nm exposure. Generally, polymers containing alicyclic hydrocarbons are used for photoresists for exposure below 200 nm. Alicyclic hydrocarbons are incorporated into the polymer for many reasons, primarily since they have relatively high carbon to hydrogen ratios which improve etch resistance, they also provide transparency at low wavelengths and they have relatively high glass transition temperatures, U.S. Pat. No. 5,843,624 discloses polymers for photoresist that are obtained by free radical polymerization of maleic anhydride and unsaturated cyclic monomers. Any of the known types of 193 nm photoresists may be used, such as those described in U.S. Pat. No. 6,447,980 and U.S. Pat. No. 6,723,488, and incorporated herein by reference.

Two basic classes of photoresists sensitive at 157 nm, and based on fluorinated polymers with pendant fluoroalcohol groups, are known to be substantially transparent at that wavelength. One class of 157 nm fluoroalcohol photoresists is derived from polymers containing groups such as fluorinated-norbornenes, and are homopolymerized or copolymerized with other transparent monomers such as tetrafluoroethylene (U.S. Pat. No. 6,790,587 and U.S. Pat. No. 6,849,377) using either metal catalyzed or radical polymerization. Generally these materials give higher absorbencies but have good plasma etch resistance due to their high alicyclic content. More recently, a class of 157 nm fluoroalcohol polymers was described in which the polymer backbone is derived from the cyclopolymerization of an asymmetrical diene such as 1,1,2,3,3-pentafluoro-4-trifluoromethyl-4-hydroxy-1,6-heptadiene (Shun-ichi Kodama et al Advances in Resist Technology and Processing XIX, Proceedings of SPIE Vol. 4690, pp. 76, 2002; U.S. Pat. No. 6,818,258) or copolymerization of a fluorodiene with an olefin (U.S. Pat. No. 6,916,590). These materials give acceptable absorbance at 157 nm, but due to their lower alicyclic content as compared to the fluoro-norbornene polymer, have lower plasma etch resistance. These two classes of polymers can often be blended to provide a balance between the high etch resistance of the first polymer type and the high transparency at 157 nm of the second polymer type. Photoresists that absorb extreme ultraviolet radiation (EUV) of 13.5 nm are also useful and are known in the art.

After the coating and baking of the photoresist, the photoresist is imagewise exposed. The exposure may be done using typical exposure equipment. The exposed photoresist is then developed in an aqueous developer to remove the treated photoresist. The developer is preferably an aqueous alkaline solution comprising, for example, tetramethyl ammonium hydroxide, more especially a 2.3 weight % of TMAH. The developer may further comprise surfactant(s). An optional heating step can be incorporated into the process prior to development and after exposure.

The process of coating and imaging photoresists is well known to those skilled in the art and is optimized for the specific type of resist used. The patterned substrate can then be dry etched with an etching gas or mixture of gases, in a suitable etch chamber to remove the exposed portions of the antireflective film, with the remaining photoresist acting as an etch mask. Various etching gases are known in the art for etching organic antireflective coatings, such as those comprising CF₄, CF₄/O₂, CF₄/CHF₃, or Cl₂/O₂.

Each of the documents referred to above are incorporated herein by reference in its entirety, for all purposes. The following specific examples will provide detailed illustrations of the methods of producing and utilizing compositions of the present invention. These examples are not intended, however, to limit or restrict the scope of the invention in any way and should not be construed as providing conditions, parameters or values which must be utilized exclusively in order to practice the present invention.

### EXAMPLES

### Formulation Example 1

To a preweighed 100 ml round-bottom flask was added 5 ml of acetoxytriethoxysilane, 1 ml phenyltriethoxysilane, 5 ml distilled water and 1 ml acetic acid. The flask was placed on a rotary evaporator and heated to 80° C. for 4 hours at a reduced pressure of 10 mm Hg. The flask containing the viscous oil was reweighed to determine the silsesquioxane (SSQ) resin weight (3.83 g), which was immediately dispersed in 31.75 g of propyleneglycolmonomethylether (PGME) to stabilize the resin and make an approximate 10.8% stock formulation of acetoxyphenylsilsesquioxane. A 3.45 g aliquot was further diluted with 9 g of PGME to make a 2.6% SSQ formulation which is referred to as Formulation Example 1. Thermosetting properties were then evaluated by spin coating a film (2000 rpm) onto a silicon wafer and baking at 250° C. Part of the wafer was then immersed in EBR 70/30 (PGME/PGMEA) for 603 seconds and followed by drying with compressed nitrogen which was blown over the wetted area. No visual change between immersed and non-immersed areas indicated that no dissolution took place in immersed areas and that the film was properly cured.

### Formulation Example 2

XR 3251 (thermoset formulation available from Dow Corning Corp, Midland, Mich.) was used as a silicon containing bottom antireflective coating (Si-BARC) which consists of a siloxane resin dispersed in methoxypropanol acetate, and was diluted to 2% (by resin weight) with PGMEA to produce Formulation Example 2. Thermosetting properties were evaluated as in Formulation Example 1 and the results were the same.

### Formulation Example 3

20099-120 (similar to XR 3251 available through Dow Corning) was diluted to 2% (by resin weight) with PGMEA to produce Formulation Example 3. Thermosetting properties were evaluated as in Formulation Example 1 and the results were the same.

### Example 4

This example illustrates a qualitative test which can be used to demonstrate surface hydrophobicity changes in cured siloxane films after soaking in an aqueous alkaline solution. Formulation Example 2 was coated onto a silicon wafer at 2000 rpm. Part of the wafer was then immersed in AZ® 300 MIF aqueous alkaline developer (available through AZ® Electronic Materials, Somerville, N.J.) for 60 seconds. The wetted area was then rinsed with distilled water and dried with a compressed nitrogen stream. A droplet of water was then placed on both the immersed and non-immersed areas. A visual inspection of the difference in the drop profile was clearly evident. A droplet placed over the soaked area spread to a flat profile indicative of a hydrophilic surface which can be wetted by water, and the droplet placed over the non-soaked area maintained a round shape with a ball-like profile indicative of a hydrophobic surface which resists wetting by water.

### Example 5

Table 1 demonstrates the surface property changes which occurred when a cured siloxane film was soaked in AZ 300 MIF aqueous developer solution. AZ 300 MIF is a 2.6N tetramethylammonium hydroxide aqueous alkaline solution. Experiments were conducted on 4 in wafers. The solutions from Formulation Examples 1 and 2 were spin coated at 2000 rpm and baked at 250° C. for 60 seconds. The wafers were then exposed to 3 minutes soak under conditions illustrated in the Table 1, followed by rinsing with distilled water and drying with compressed nitrogen gas stream. Water contact angles measurements illustrate hydrophobicity changes to the films surface that occur after employing the aqueous alkaline treatment processes.

TABLE 1
Water contact angle values measured after exposing cured siloxane
films to aqueous alkaline solution, rinsing and drying.

| | | | Contact | Contact |
|---|---|---|---|---|
| | | | Angle for | Angle for |
| | | Temperature | Formulation | Formulation |
| Test | Conditions | (° C.) | Example 1 | Example 2 |
| 1 | no soak | | 48° | 74° |
| 2 | AZ 300 MIF | 25 | 25° | 56° |
| | developer | | | |
| 3 | Water | 25 | 48° | 69° |
| 4 | AZ 300 MIF | 70 | 0° | — |
| | developer | | | |
| 5 | Water | 70 | 48° | 69° |

### Example 6

Table 2 demonstrates the surface properties changes which occur when soaking a cured siloxane film in AZ 300 MIF aqueous developer solution. Experiments were conducted on 8 in wafers, Formulation Example 3 was spin coated at 2000 rpm and baked at 250° C. for 60 seconds. A puddle of AZ 300 MIF developer was placed on top of the wafer for times indicated in the table and then rinsed with distilled water and spun dried. Water contact angles measurements illustrate hydrophobicity changes to the films surface that occur after employing the invented processes.

TABLE 2
Water contact angles lowering from alkaline puddle development times.

| | | Contact |
|---|---|---|
| | | Angle for |
| | | Formulation |
| Wafer | Puddle time (s) | Example 3 |
| 1 | 0 | 90° |
| 2 | 180 | 63° |
| 3 | 600 | 63° |

### Example 7

Formulation Example 3 was used as a silicon containing bottom antireflective coating (Si-BARC) in a trilayer stack to test the impact of changing the surface hydrophobicity of the Si-BARC on the photoresist profiles. Three 8 in silicon wafers were coated with 37 nm film of AZ ArF IC₅D (antireflective coating solution available from AZ Electronic Material, Somerville, N.J.) and then 70 nm coating of film produced from spin coating Formulation Example 3. Treatment of the 3 wafers was as follows:

Wafer 1 reference, no treatment

Wafer 2, AZ 300 MIF developer puddle was placed on top of the wafer for 180 seconds and then rinsed with distilled water and spun dried

Wafer 3, AZ 300 MIF developer puddle was placed on top of the wafer for 600 seconds and then rinsed with distilled water and spun dried

After this a 190 nm of a 193 nm acrylate photoresist, AZ® Exp T83641 available from AZ Electronic Material, Somerville, N.J., was coated. Wafers were then imaged using a 193 nm S306 Nikon scanner interfaced to a TEL ACT12 wafer track and developed in AZ® 300 MIF Developer. The scanning electron micrographs of the imaged photoresist profiles showed that for 80 nm (1:1 pitch) lines there was less scumming with Si-BARCs that underwent developer puddle (Wafers 2 and 3) than without the treatment (wafer 1). An improvement of the photoresist profiles was seen by reducing the surface hydrophobicity of Si-BARC films using the alkaline solution treatment.

1. A process for imaging a photoresist coated over an antireflective coating comprising;
a) forming an antireflective film from an antireflective coating composition, where the composition comprises a siloxane polymer;
b) treating the antireflective film with an aqueous alkaline treating solution;
c) rinsing the antireflective film treated with an aqueous rinsing solution;
d) forming a coating of c photoresist aver the film of the antireflective coating composition,
e) imagewise exposing the photoresist film; and,
f) developing the photoresist with an aqueous alkaline developing solution.

2. The process of claim 1I where the antireflective composition further comprises a curing agent.

3. The process of claim 1, where the antireflective composition further comprises a crosslinking agent.

4. The process of claim 1, where the antireflective composition is free of a curing agent.

5. The process of claim 1, where the siloxane polymer comprises base hydrolysable groups.

6. The process of claim 1, where the siloxane polymer comprises base hydrolysable SiX groups, where X is selected from alkoxy, chloride, acyloxy, and ketoxime groups.

7. The process of claim 1, where the aqueous alkaline treating solution comprises tetramethyl ammonium hydroxide.

8. The process of claim 1, where the rinsing solution is water.

9. The process of claim 1, where the photoresist comprises a polymer and a photoacid generator.

10. The process of claim 1, where the imagewise exposure is at a wavelength selected from 248 nm, 193 nm, 157 nm, and 13.5 nm.

11. The process of claim 1I where the developing solution comprises tetramethyl ammonium hydroxide.

12. The process of claim 1, where the antireflective film after treatment with an aqueous alkaline solution has a water contact angle of about 500 to about 75°.
